(19) United States
(12) Patent Application Publication
(10) Pub. No.: US 2020/0029472 A1
(43) Pub. Date: Jan. 23, 2020

(54) CONTROL UNIT FOR A VEHICLE

(71) Applicant: ZF Friedrichshafen AG, Friedrichshafen (DE)

(72) Inventors: Viktor Rakoczi, Immenstaad am Bodensee (DE); Michael KECKEISEN, Meckenbeuren (DE); Oliver BRIEMLE, Friedrichshafen (DE); Wolfgang VIEWEGER, Langenargen (DE)

(73) Assignee: ZF Friedrichshafen AG, Friedrichshafen (DE)

(21) Appl. No.: 16/509,953

(22) Filed: Jul. 12, 2019

(30) Foreign Application Priority Data
Jul. 19, 2018 (DE) 102018212076.5

(51) Int. Cl. H05K 7/20; B60R 16/023

(52) U.S. Cl. CPC H05K 7/20863; B60Y 2306/05; H05K 7/20881; B60R 16/0231

(57) ABSTRACT

A control device (SG) for a vehicle is proposed, which contains at least one electronic component (GPU). Furthermore, there is at least one fan (F1), and one air channel (LK), which enables air to flow (LS) from a first side of the at least one electronic component (GPU) to the first fan (F1), wherein the air flow (LS) then flows past a second side of the at least one electronic component (GPU) after passing through the first fan.

The invention relates to a control device for a vehicle according to the subject matter of the independent claim.

The control device for a vehicle according to the invention that has the features of the independent claim has the advantage that there is an air channel that enables an air flow from a first side of an electronic component, e.g. a processor, to the fan, wherein the air flow continues to flow past a second side of the electronic component. This enables a cooling of both sides of the electronic component. The solution according to the invention requires little space, and enables a targeted ventilation of so-called heat spots (heat centers) in particular. The closed air circulation within the control device enables a good thermal bonding to the control device housing itself. Furthermore, with the control device according to the invention it is possible to obtain a control device that can be sealed off without a great deal of effort, because this cooling concept only takes place inside the control device itself. The control device according to the invention also does not require maintenance because there are no contaminants and the control device is hermetically sealed. Furthermore, audible sounds emitted by the fan are minimized by the sealing of the control device. Moreover, the product itself is sealed, forming a stand-alone product.

The control device for a vehicle according to the invention thus has at least one electronic component, at least one fan, an air channel that enables air to flow from one side of the at least one electronic component to the fan, wherein the air flow continues to flow past a second side of the at least one electronic component, preferably after this fan.

In the present case, a control device is understood to be a control device in particular that has a housing, e.g. made of metal or plastic, or a composite thereof, in which there is at least one processor in the form of an electronic component. It is provided in particular that this control device has numerous processors, e.g. a so-called graphics processor, for deriving different functions from the sensor signals conveyed to the control device. In particular, artificial intelligence can be used for this, which evaluates the sensor data by means of the graphical graphics processor through neural networks, in order to generate control signals that are conveyed to the vehicle systems for the control thereof.

A vehicle is understood to be a passenger car or truck, or any other vehicle, e.g. driverless vehicles in logistics centers.

As stated above, the at least one electronic component can be a processor in particular, preferably a graphic processor. It can also be some other electronic component that requires cooling. Processors require cooling because of their high level of computing power and the corresponding heat discharge.

A fan is understood to be a ventilator, defined in greater detail by the dependent claims. This fan generates an air flow, which is either drawn in or discharged, for which appropriate technologies are used.

The air channel is a structural means that enables the air to flow from the first side of the electronic component to the fan. The air channel can be formed by a hose with a round cross section or a channel with a rectangular cross section. It can be made of plastic, metal, or composites thereof. Any other suitable material can be used in the present case. The air channel should have a constant cross section over its entire length, without any breaks or corners, such that its course is continuous. The air channel is placed above the electronic component as close as possible.

The air flow is understood to be the movement of air drawn in by the fan.

The first and second sides of the electronic component are understood to be the upper and lower sides, for example, between which other modules can be located, i.e. the air flow does not need to be connected directly to the electronic component, and other components can be located between the air flow and the electronic component. The idea is that heat from the electronic component is conducted to these other components, and is then discharged.

Advantageous embodiments of the control device for a vehicle specified in the independent claim can be obtained with the measures and developments listed in the dependent claims.

The at least one first heat pipe is advantageously placed in the region of the air flow, on the second side of the at least one electronic component. As a result, the air flow can be cooled by this heat pipe. A heat pipe is understood in the present case to be a heat pipe. A heat pipe transfers heat, which allows for a high heat flow density through the use of the condensation heat of a medium. This means that large heat quantities can be transported through small cross sections. Such heat pipes fundamentally contain a hermetically encapsulated volume, usually in the form of a tube. This is filled with a working medium, e.g. water or ammonia, which fills the volume to a small extent in the liquid form, and to a larger extent in the gaseous form. There is a heat transferring surface therein for heat sources and heat sinks.

When it is heated, the working medium vaporizes. As a result, the pressure is increased locally in the vapor chamber above the surface of the liquid, resulting in a slight drop in pressure in the heat pipe. The resulting vapor consequently flows to a location with a lower temperature, where it condenses. The temperature increases at this location as a result of the condensation heat that has been released. The previously absorbed latent heat is discharged into the environment. The now liquid medium then returns to the location where the heat is introduced as a result of gravity, or capillary forces in the case of a heat pipe.

Because the chamber contains both gaseous and liquid forms of the fluid, the system belongs to the field of wet vapor. As a result, at a specific pressure in the heat pipe, there is a precise specific temperature. Because the pressure differences in the heat pipe are usually only a few Pascals, the resulting temperature difference between an evaporator and a condenser is also very small, amounting to no more than a few degrees Kelvin. A heat pipe therefore has a very low heat resistance. The region between the evaporator and the condenser is practically isothermal.

Because the heat discharge takes place indirectly, via the substance-based transport of latent heat (evaporation-condensation heat), the range of use for a heat pipe is limited to the temperature range between the melting point and the critical point of the working fluid. All forces acting on the working medium also have an effect on the actual heat transfer performance. Gravity can supplement or partially offset the capillary forces in heat pipes.

There is also advantageously at least one second heat pipe on the first side of the at least one electronic component.

There is also a so-called thermal interface material (TIM), in particular a gap filler, between the at least one electronic component and the first and second heat pipes, respectively. As an alternative to the gap filler, a so-called heat conducting film can also be used. It has the same purpose, and exhibits advantages with regard to the processing thereof. A gap filler is usually a paste-like substance with silver particles for enhancing the thermal conductivity.

A TIM is used for thermal transfer. This thermal transfer takes place between two flat surfaces that are securely fastened to one another. The gap filler also compensates for any mechanical tolerances. It also fulfills a sealing function, a so-called hermetic sealing.

The gap filler, or a heat transfer film, is not only used in the structure described above, but also when assembling the control housing, which is comprised of two or more parts, e.g. an upper shell and a lower shell.

The interior of the hermetically sealed control device is advantageously filled with nitrogen. This can be pressurized to a certain extent. This nitrogen atmosphere prevents condensation from forming at cold temperatures or when the temperature changes quickly.

It is also advantageous when the at least one electronic component is placed on a so-called performance board, wherein the performance board is located on a carrier board. This results in a construction that allows air to flow beneath the electronic component on this performance board. A performance board is a board that can be populated with electronic components, and also provides connections therebetween. This can be accomplished in a number of ways.

In order to obtain a hardware modularity, or a functionally scalable system, it is proposed that the aforementioned structure for the control device contains numerous performance boards with nearly identical hardware and software.

It is also intended that there are numerous performance boards on the carrier board, wherein the air channel is designed for the respective electronic component, in order to generate an appropriate air flow. This results in a structure that contains numerous processors, for example, located on respective performance boards, which have their own fans, which enables a respective air flow through the design of the air channel. The fans can be identical or they can differ from one another. With identical fans, the operation of the respective fan is adjusted to the requirements for cooling the respective electronic component. It is also possible, however, to use just one fan, which serves the various channels. A respective dedicated fan has the advantage that if one of the fans malfunctions, this does not result in a complete breakdown of the entire control device. As a result, it is possible to provide an appropriate air flow for obtaining an optimal cooling effect, depending on the anticipated thermal development.

There is also advantageously at least one second fan located outside the housing, wherein the housing encompasses the electronic component and the at least one first fan, and the air channel. This second, exterior fan provides a further cooling effect in that it removes the heat generated in the control device.

For this, the housing can advantageously exhibit a first ribbed structure on at least part of its exterior. This fluted cooling structure results in a more efficient heat exchange. The ribs increase the turbulence of the flow. This increases the efficiency of a heat flow from the interior to the exterior. In order to thus obtain a cooling effect through a forced flow, turbulence is necessary in the contours of the cooling element. These turbulences are obtained through the ribs or corrugated cooling structure or rib structure.

The housing also advantageously has a second ribbed structure on at least part of its interior. As a result, the same effect is also obtained inside, and the heat flow from the interior to the exterior is thus further improved. The ribbed structures can be made of metal. Other suitable materials can also be used in the present case, e.g. silicon carbide.

Advantageously, the at least one first fan in the control device is a radial fan, and the at least one second fan on the outside of the housing is an axial fan. A so-called diagonal fan can also be used, forming a hybrid of the other two types. With an axial fan, the rotational axis of the axial rotor is parallel, or axial to the air flow. The air is moved by the axial rotor in a manner similar to that with an airplane propeller or a ship propeller. The advantage with axial fans is that they do not need to be very large to move a large quantity of air, particularly in terms of their depth. Radial fans draw in air in a direction parallel, or axial, to the drive axle of the radial fan, and this air flow is deflected 90° by the rotation of the radial rotor, and discharged radially. There are radial fans that draw in air from one side and from both sides, with and without a housing. The use of the fan can be derived from the so-called Cordier diagram.

When a fan is described in terms of cooling criteria, there are always two opposing variables:

Axial fans: higher volume flow, difficult to generate pressure
Radial fans: possible to generate higher pressure, lower volume flow

Because of the construction of a radial fan, it is advantageously possible to thermally and mechanically connect the fan housing to the interior surface of the control device, in order to discharge the heat generated by the fan itself, and the heat in the interior of the control device.

The standing radial fan preferably has a metal panel on the radial (lateral) surfaces, which is connected to the housing at the top. The heat path is as follows: The heat is formed in the motor, or the electronics of the motor. It is then conducted to the metal panel. The heat is then conducted into the ambient air via the connection to the housing.

Vertical plastic surfaces (walls) are advantageously placed between the individual performance boards and the carrier board in order to obtain independent thermal “sub”-systems, and particularly to obtain a stable equilibrium between the volume flow and the pressure losses. In particular if a fan breaks down, this results in an instable volume flow and pressure loss state, and the intact fans would not function in specified operating points. The walls are therefore preferably attached to the respective undersurface of the respective performance board, e.g. with releasable or permanent connecting methods. Alternatively or additionally, these walls can also be installed on or under the motherboard, and then extend toward the performance board.

The cooling structures (ribbed structure) placed on the inner surface of the housing are oriented along the direction of flow (parallel thereto), in order to ensure that the air circulates.

The fundamental invention presented herein offers the advantage that there is not only one dominant thermal path, but instead, heat can be discharged via nearly all six sides of the housing. This results in an efficient cooling of the control device.

With the fundamental invention, it is possible to cool the heat emitting components attached to the upper and lower surfaces of the performance board in a targeted manner, depending on where the opening in the air channel is located.

The air channel draws the air away from the upper surface of the performance board, and blows it into the cooling structure between the performance board and the motherboard. The exchange with the housing takes place at the outlet of the cooling structure. In this manner, both the drawing of air, as well as the blowing of air by the fan are used for cooling purposes.

Exemplary embodiments of the invention are shown in the drawings, and shall be explained in greater detail in the following description.

Therein:

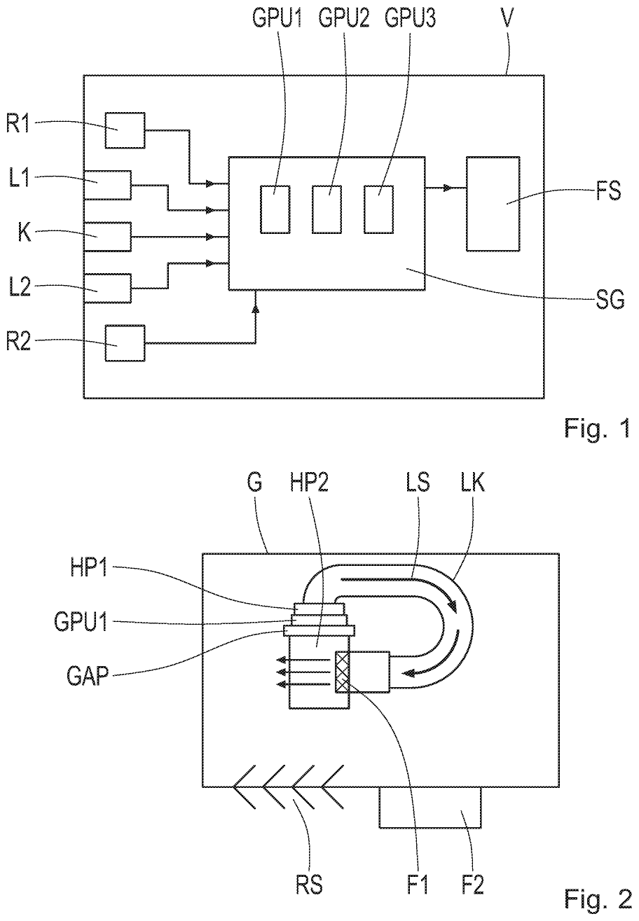

FIG. 1 shows a block diagram of the control device according to the invention, in a vehicle with devices connected thereto;

FIG. 2 shows an illustration of the control device according to the invention, with an embodiment of an air channel and an outer cooling; and

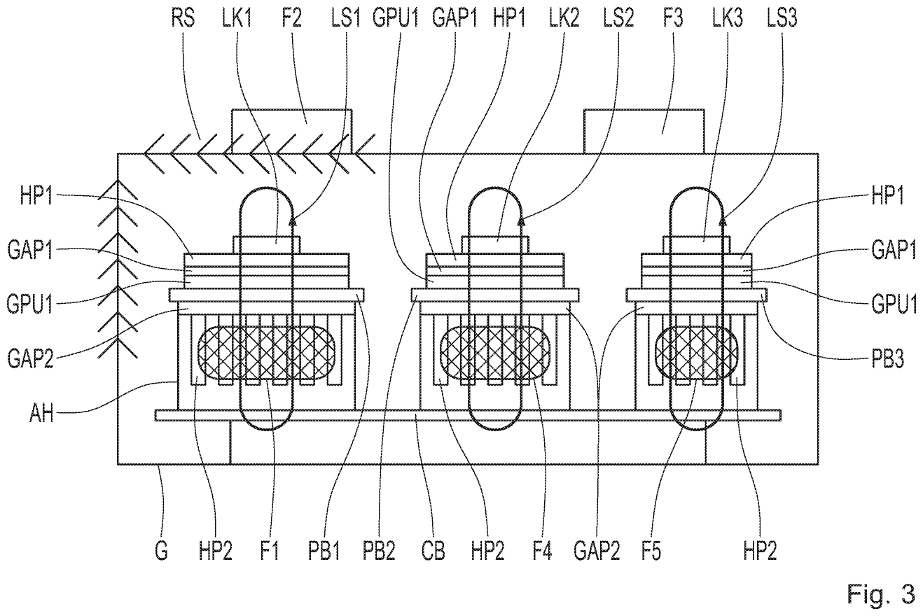

FIG. 3 shows an illustration of the control device with numerous electronic components on different performance boards.

FIG. 1 shows the control device SG according to the invention in a block diagram, with sensors connected thereto, radar sensors R1 and R3, lidar sensors L1 and L2, and a camera K. More or fewer sensors of the same or different types can also be connected thereto. The sensor data therefrom are evaluated in the present case by three graphic processors GPU1, GPU2, and GPU3 in the control device SG, for example. A vehicle actuator FS is controlled, by way of example, with the results of the evaluation. These actuators can be a steering system, braking system, transmission, gas pedal, display, audio system, or other vehicle system.

FIG. 2 shows the control device SG with an exemplary interior configuration. A housing G has inner and outer ribbed structures RS, which partially encompass the housing. These outer and inner ribbed structures RS generate turbulences, as explained above, in the air flow caused by the fan F2. This discharges the heat from the control device. By way of example, a structure containing a graphic processor GPU 1 as an electronic component is located inside the housing G of the control device SG. The graphic processor GPU1 is covered by a heat pipe HP1, to which an air channel LK is connected. There is a so-called gap filler GAP underneath the graphic processor GPU 1, which forms the connection to the heat pipe HP2. The air channel conducts just one air flow LS, which is caused by the fan F1 at the end of the air channel, to the heat pipe HP2. As a result, the air current can be further cooled by the heat pipe HP2.

FIG. 3 shows the housing G again, with inner and outer ribbed structures RS. Two fans F2 and F3 are located outside the control device on the housing G, which cause the heat transfer by means of the ribbed structure RS, as described above, from the housing of the control device to the exterior. There are three structures with graphic processors GPU1, which are each covered by a gap filler GAP1, and to each of which a heat pipe HP1 is connected in turn. There is a respective air channel LK1, LK2 and LK3 above each heat pipe. There is a respective performance board PB1, PB2 and PB3 under each graphic processor. There is a gap filler GAP2 under each performance board, which in turn is connected to the underlying heat pipe HP2. Each of the three structures has a dedicated fan F1, F4, and F5, which generate different air flows LS1, LS2 and LS3, depending on the thermal development. These can also have an adaptive configuration through the use of sensors. The performance boards PB1, PB2, PB3 are placed on the so-called carrier board on top of spacers AH. The carrier board is indicated by CB.

### REFERENCE SYMBOLS

V vehicle
L1, L2 lidar
R1, R2 radar
K camera
SG control device
GPU1-GPU3 graphic processors
FS vehicle system
G housing
RS inner and outer ribbed structures
F1-F5 fans
HP1, HP2 heat pipes
GAP1, GAP2 gap fillers
LS air flow
LKair channel
PB1-PB3 performance boards
CB carrier board
AH spacer
LS1-LS3 air flows

1. A control device for a vehicle that has:
at least one electronic component
at least one first fan
an air channel, that enables air to flow from a first side of the at least one electronic component to the first fan, wherein the air flow flows past the second side of the at least one electronic component.

2. The control device according to claim 1, wherein at least one first heat pipe is placed in the region of the air flow on the second side of the at least one electronic component.

3. The control device according to claim 2, further comprising there is at least one second heat pipe on the first side of the at least one electronic component.

4. The control device according to claim 3, further comprising that there is a gap filler located between the at least one electronic component and each of the first and second heat pipes.

5. The control device according to claim 4, wherein the at least one electronic component is located on a performance board, wherein the performance board is located on a carrier board.

6. The control device according to claim 5, further comprising a plurality of performance boards located on the carrier board, wherein the air channel designed to generate an air flow corresponding to the respective electronic component.

7. The control device according to claim 1, further comprising at least one second fan is located outside a housing that encompasses the at least one electronic component, the at least one first fan, and the air channel.

8. The control device according to claim 7, wherein the housing has a ribbed structure on at least part of an exterior of the housing.

9. The control device according to claim 8, wherein the housing has a ribbed structure on at least part of an interior of the housing.

10. The control device of claim 7, wherein the at least one first fan is a radial fan, and/or the at least one second fan is an axial fan.

11. The control device according to claim 1, wherein the control device is filled with nitrogen.

12. The control device of claim 6, wherein the plurality of performance boards each comprise undersurfaces, and further comprising walls that are provided upon the undersurfaces of each of the plurality of performance boards.

13. The control device according to claim 9, wherein the ribbed structure contains parallel elements.

14. The control device according to claim 10, wherein the radial fan is thermally connected to the housing.
